(19) United States
(12) Patent Application Publication
(10) Pub. No.: US 2016/0254294 A1
(43) Pub. Date: Sep. 1, 2016

(54) MANUFACTURE METHOD OF LTPS AND MANUFACTURE METHOD OF TFT SUBSTRATE

(71) Applicant: SHENZHEN CHINA STAR OPTOELECTRONICS TECHNOLOGY CO., LTD., Shenzhen, Guangdong (CN)

(72) Inventor: Ya LI, Shenzhen, Guangdong (CN)

(73) Assignee: Shenzhen China Star Optoelectronics Technology Co., Ltd., Shenzhen, Guangdong (CN)

(21) Appl. No.: 14/423,124

(22) PCT Filed: Feb. 6, 2015
(86) PCT No.: PCT/CN2015/072349

§ 371 Date: Feb. 21, 2015

(30) Foreign Application Priority Data
Oct. 30, 2014 (CN) 201410605937.1

(51) Int. Cl. H01L 27/12; H01L 21/306; H01L 29/66; H01L 21/02; H01L 21/324

(52) U.S. Cl. CPC H01L 27/1277; H01L 27/1218; H01L 21/02532; H01L 21/02592; H01L 21/02672; H01L 21/324; H01L 21/02425; H01L 21/02164; H01L 21/0217; H01L 29/66757; H01L 21/30604; H01L 27/1222

(57) ABSTRACT

The present invention provides manufacture methods of LTPS and a TFT substrate. The manufacture method of LTPS comprises steps of: step 1, providing a substrate (1); step 2, deposing a buffer layer (2) on the substrate (1); step 3, plating a metal mesh film (3) on the buffer layer (2); step 4, deposing an amorphous silicon layer (4) on the metal mesh film (3); step 5, implementing a rapid thermal annealing process to the amorphous silicon layer (4), and the amorphous silicon layer (4) crystallizes and converts to be a polysilicon layer (5); step 6, removing the metal mesh film (3). The method can effectively reduce the crystallization point, and shorten the crystallization time, and decrease the cost of manufacturing the polysilicon thin film in large scale, and improve the crystallization result to make the crystalline grain bigger and more even.

### FIELD OF THE INVENTION

The present invention relates to a display technology field, and more particularly to a manufacture method of LTPS and a manufacture method of a TFT substrate employing the method.

### BACKGROUND OF THE INVENTION

With the development of panel displays, the high resolution and low power consumption panels has constantly been demanded. The Low Temperature Poly-Silicon (LTPS) possesses higher electron mobility and draws the attentions of the industry related to the Liquid Crystal Display (LCD) and the Organic Light Emitting Diode (OLED) to be considered an important material of achieving the low cost full color panel display. For panel display, the LTPS material possesses advantages of high resolution, fast response, high brightness, high aperture ratio, low power consumption, et cetera. Moreover, the LTPS can be manufactured under condition of low temperature and applicable for manufacturing C-MOS circuit. Therefore, it has been widely researched and developed to satisfy demands of high resolution and low power consumption.

The LTPS is a branch of the poly-Si technology. The arrangement status of the poly-Si molecule structure in one crystalline grain is in good order and directional. Therefore, the electron mobility is 200-300 times faster than the disorderly arranged a-Si, which tremendously promotes the response speed of the panel display. The present manufacture methods of the LTPS are: crystallization processes, Chemical Vapor Deposition (CVD), Solid Phase Crystallization (SPC), Metal-Induced Crystallization (MIC), Metal-Induced Lateral Crystallization (MILC), Excimer Laser Annealing (ELA) and et cetera.

Please refer FIG. 1 to FIG. 5. A common manufacture method of a TFT substrate utilizing the LTPS mainly comprises steps of: step 1, providing a substrate 100; step 2, deposing a buffer layer 200 on the glass substrate 100; step 3, deposing an amorphous silicon layer 400 on the buffer layer 200; step 4, employing the present crystallization processes, CVD, SPC, MIC, MILC or ELA, to make the amorphous silicon layer 300 to convert to be a polysilicon layer 400; step 5, implementing a patterning process to the polysilicon layer 400 and forming a polysilicon semiconductor layer 450 with photo and etch processes; step 6, sequentially forming a gate insulation layer 500, a gate 600, an interlayer insulation film 700, a source/a drain 800 on the polysilicon semiconductor layer 450.

The sizes of the crystalline grain obtained by utilizing the CVD crystallization process is particularly small and the deposition rate is low; the traditional SPC crystallization process requires high temperature and long process time, which easily results in the deformation of the substrate and manufacture cost is higher; the metal residues of the polysilicon layer obtained with the MIC or MILC crystallization processes are more and leads to worse TFT electric property; the density of the gate states of the polysilicon obtained with the ELA crystallization process is low which is difficult to manufacture the polysilicon thin film in a large scale and the ELA equipment is expensive.

### SUMMARY OF THE INVENTION

An objective of the present invention is to provide a manufacture method of LTPS, which can effectively reduce the crystallization point, and shorten the crystallization time, and decrease the cost of manufacturing the polysilicon thin film in a large scale, and improve the crystallization result to make the crystalline grain bigger and more even.

Another objective of the present invention is to provide a manufacture method of a TFT substrate, which can reduce the crystallization point, and shorten the crystallization time, and improve the crystallization result to make the crystalline grain bigger and more even for promoting the electric property of the TFT.

For realizing the aforesaid objectives, the present invention provides a manufacture method of LTPS, comprising steps of:

step 1, providing a substrate;

step 2, deposing a buffer layer on the substrate;

step 3, plating a metal mesh film on the buffer layer;

step 4, deposing an amorphous silicon layer on the metal mesh film;

step 5, implementing a rapid thermal annealing process to the amorphous silicon layer, and metal material in the metal mesh film and silicon in the amorphous silicon layer are combined to be metal silicide to induce the amorphous silicon layer to crystallize and convert to be a polysilicon layer;

the metal mesh film having metal silicide is moved up on the polysilicon layer;

step 6, removing the metal mesh film having metal silicide.

Material of the metal mesh film is Aluminum.

In the step 5, the temperature of the rapid thermal annealing process is 600° C. and the time is 10 minutes.

The buffer layer is a single SiNx layer, a single SiOx layer, a double SiNx layer, a double SiOx layer or a combination of SiNx layer and SiOx layer.

The present invention further provides a manufacture method of a TFT substrate, comprising steps of:

step 1, providing a substrate;

step 2, deposing a buffer layer on the substrate;

step 3, plating a metal mesh film on the buffer layer;

step 4, deposing an amorphous silicon layer on the metal mesh film;

step 5, implementing a rapid thermal annealing process to the amorphous silicon layer, and metal material in the metal mesh film and silicon in the amorphous silicon layer are combined to be metal silicide to induce the amorphous silicon layer to crystallize and convert to be a polysilicon layer;

the metal mesh film having metal silicide is moved up on the polysilicon layer;

step 6, removing the metal mesh film having metal silicide;

step 7, implementing a patterning process to the polysilicon layer and forming a polysilicon semiconductor layer;

step 8, sequentially forming a gate insulation layer, a gate, an interlayer insulation film, a source/a drain on the polysilicon semiconductor layer, and the source/the drain are connected to the polysilicon semiconductor layer.

Material of the metal mesh film is Aluminum.

In the step 5, the temperature of the rapid thermal annealing process is 600° C. and the time is 10 minutes.

The buffer layer is a single SiNx layer, a single SiOx layer, a double SiNx layer, a double SiOx layer or a combination of SiNx layer and SiOx layer.

The step 7 employs photo and etch processes to implement the patterning process to the polysilicon layer.

The benefits of the present invention are: according to the manufacture methods of LTPS and the TFT substrate of the present invention, the amorphous silicon layer is deposed on the metal mesh film and the rapid thermal annealing process is implemented to the amorphous silicon layer, and metal material in the metal mesh film and silicon in the amorphous silicon layer are combined to be metal silicide to induce the amorphous silicon layer to crystallize and convert to be a polysilicon layer. Then, the metal mesh film is removed to make the amorphous silicon layer rapidly crystallize at lower temperature, which can effectively reduce the crystallization point, and shorten the crystallization time, and decrease the cost of manufacturing the polysilicon thin film in a large scale, and improve the crystallization result to make the crystalline grain bigger and more even for promoting the electric property of the TFT.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a diagram of the step 2 of a manufacture method of a TFT substrate utilizing LTPS according to prior art;

FIG. 2 is a diagram of the step 3 of a manufacture method of a TFT substrate utilizing LTPS according to prior art;

FIG. 3 is a diagram of the step 4 of a manufacture method of a TFT substrate utilizing LTPS according to prior art;

FIG. 4 is a diagram of the step 5 of a manufacture method of a TFT substrate utilizing LTPS according to prior art;

FIG. 5 is a diagram of the step 6 of a manufacture method of a TFT substrate utilizing LTPS according to prior art;

FIG. 6 is a flowchart of a manufacture method of LTPS according to the present invention;

FIG. 7 is a flowchart of a manufacture method of a TFT substrate according to the present invention;

FIG. 8 is a diagram of the step 2 of manufacture methods of LTPS and a TFT substrate according to the present invention;

FIG. 9 is a diagram of the step 3 of manufacture methods of LTPS and a TFT substrate according to the present invention;

FIG. 10 is a diagram of the step 4 of manufacture methods of LTPS and a TFT substrate according to the present invention;

FIG. 11 is a diagram of implementing the rapid thermal annealing process in the step 5 of manufacture methods of LTPS and a TFT substrate according to the present invention;

FIG. 12 is a diagram of manufacture methods of LTPS and a TFT substrate according to the present invention after the step 5 is accomplished;

FIG. 13 is a diagram of the step 6 of manufacture methods of LTPS and a TFT substrate according to the present invention;

FIG. 14 is a diagram of the step 7 of a manufacture method of a TFT substrate according to the present invention;

FIG. 15 is a diagram of the step 8 of a manufacture method of a TFT substrate according to the present invention.

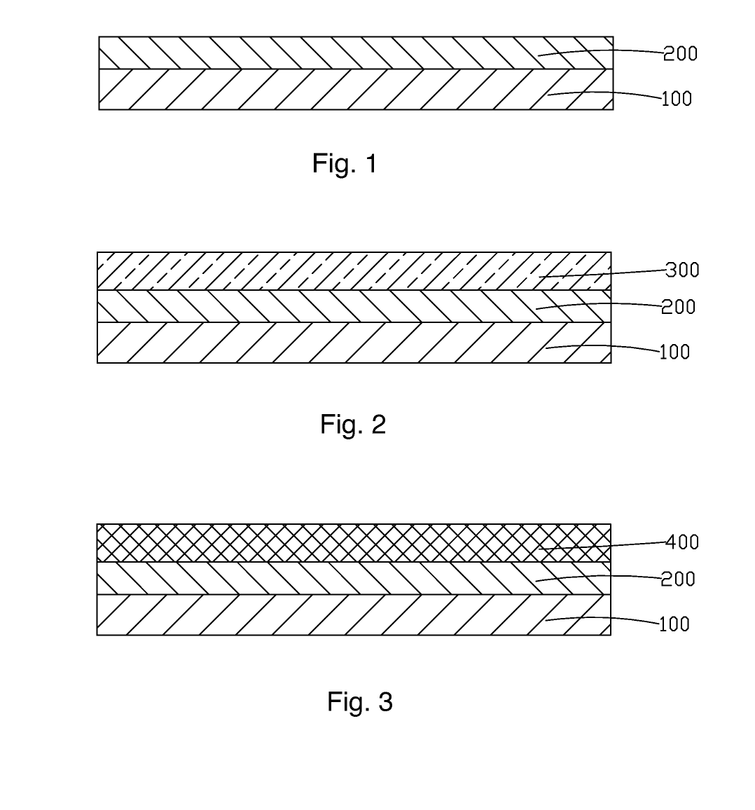

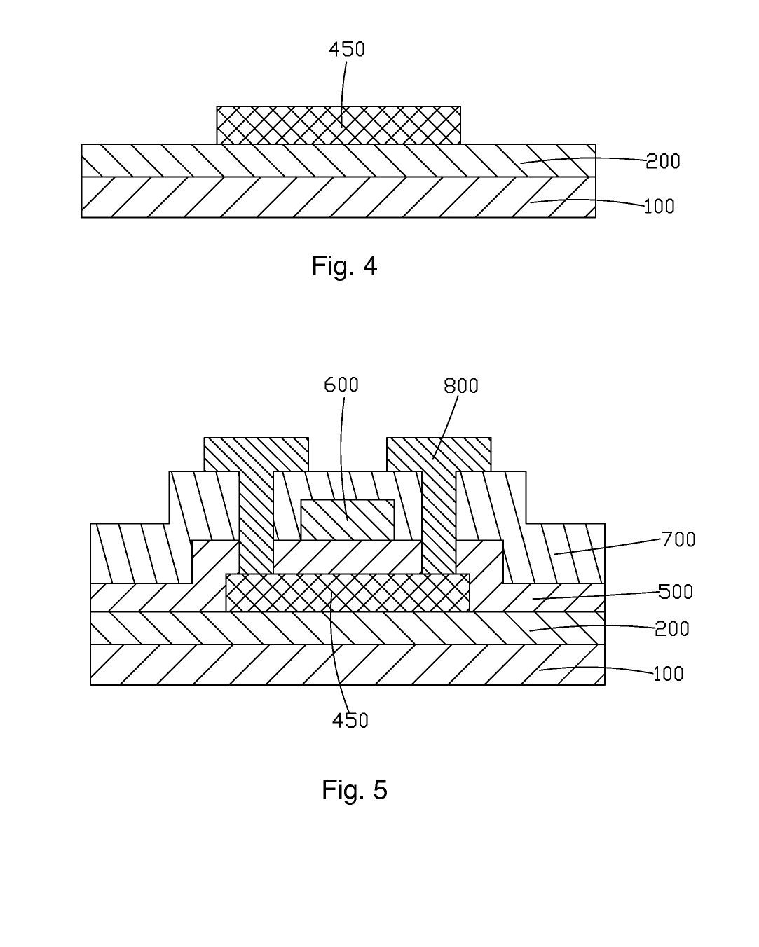

### DETAILED DESCRIPTION OF PREFERRED EMBODIMENTS

For better explaining the technical solution and the effect of the present invention, the present invention will be further described in detail with the accompanying drawings and the specific embodiments.

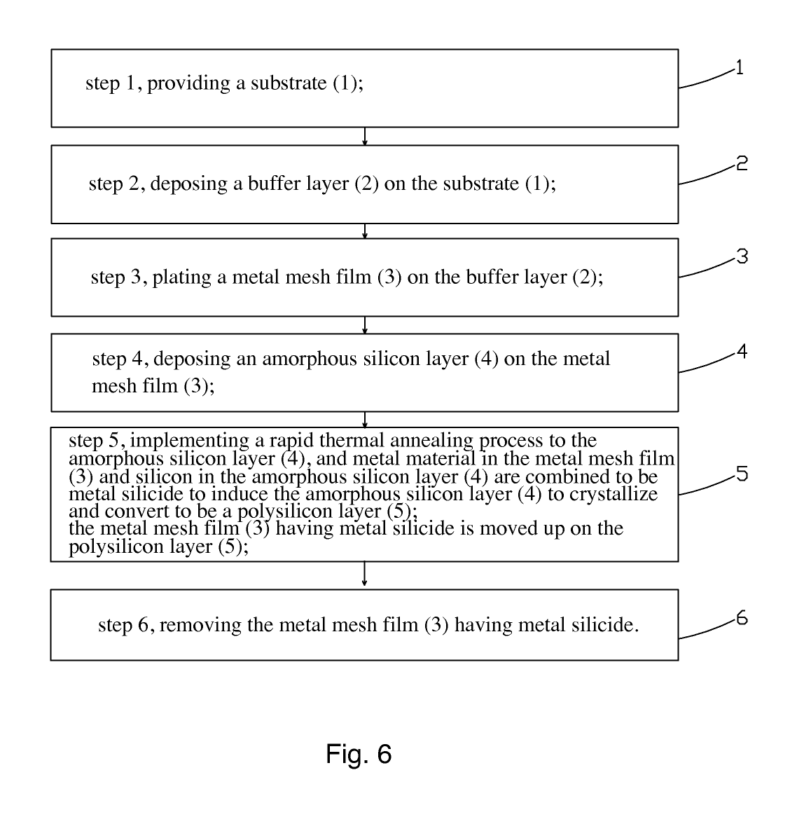

Please refer to FIG. 6 and FIGS. 8 to 13. The present invention provides a manufacture method of LTPS, comprising steps of:

step 1, providing a substrate 1.

The substrate 1 is a common transparent substrate. Preferably, the substrate 1 is a glass substrate.

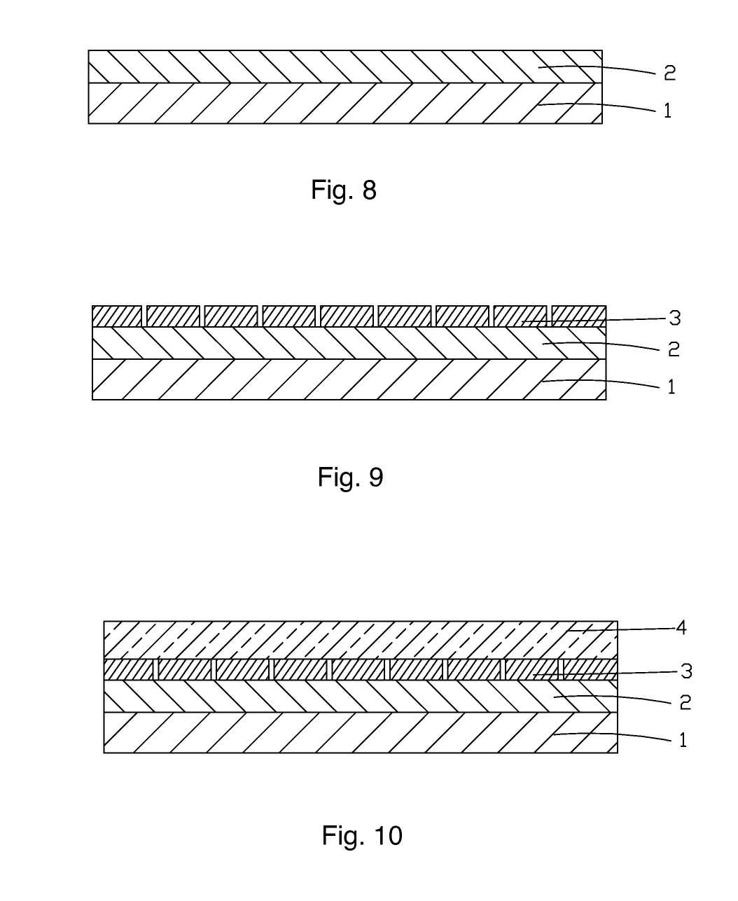

step 2, as shown in FIG. 8, deposing a buffer layer 2 on the substrate 1.

Specifically, the buffer layer 2 can be a single SiNx layer, a single SiOx layer, a double SiNx layer, a double SiOx layer or a combination of SiNx layer and SiOx layer.

step 3, as shown in FIG. 9, plating a metal mesh film 3 on the buffer layer 2.

Specifically, the material of the metal mesh film 3 is Aluminum.

step 4, as shown in FIG. 10, deposing an amorphous silicon layer 4 on the metal mesh film 3.

After the step 4 is accomplished, the amorphous silicon layer 4, the metal mesh film 3, the buffer layer 2 stack up from top to bottom in orders.

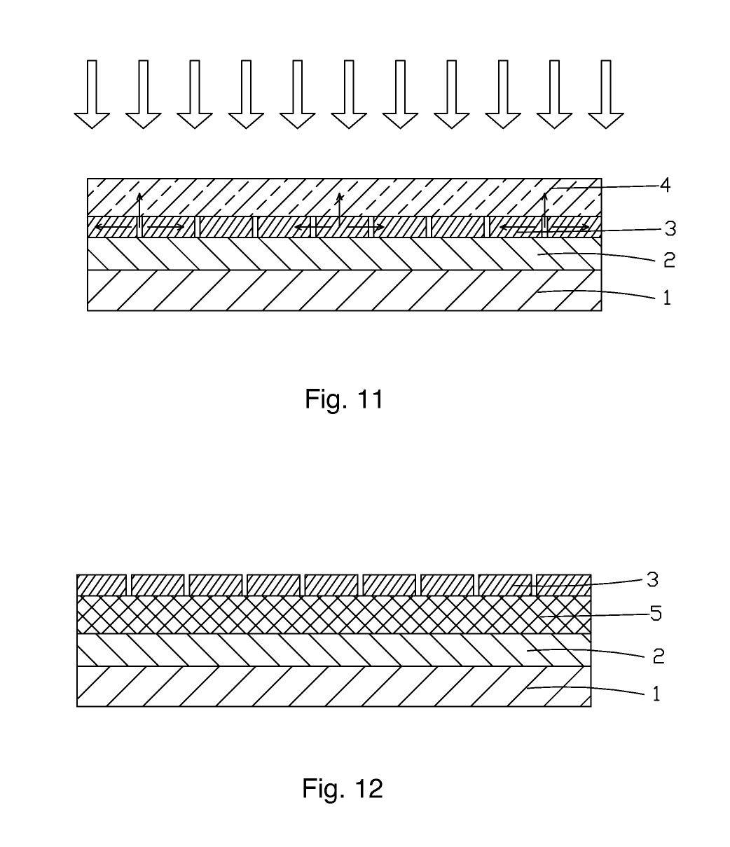

step 5, as shown in FIG. 11, FIG. 12, implementing a rapid thermal annealing (RTA) process to the amorphous silicon layer 4, and metal material in the metal mesh film 3 and silicon in the amorphous silicon layer 4 are combined to be metal silicide to induce the amorphous silicon layer 4 to crystallize and convert to be a polysilicon layer 5.

Furthermore, the step 5 utilizes the eutectic point characteristic of the metal and silicon interface, and the RTA process under 600° C. with 10 minutes can crystallize amorphous silicon layer 4 to convert to be the polysilicon layer 5. The RTA temperature is effectively reduced. The RTA time is shortened. The amorphous silicon layer 4 rapidly crystallize at lower temperature and no special requirement do for the substrate 1. A common substrate can endure 600° C. The manufacture cost is decreased and application for manufacturing the polysilicon thin film in large scale is possible.

In the RTA process, the metal material in the metal mesh film 3 and silicon in the amorphous silicon layer 4 are combined to be metal silicide to induce the amorphous silicon layer 4 to crystallize. The mesh structure of the metal mesh film 3 is beneficial to induce lateral crystallization with metal which the crystallization is more thoroughly accomplished to make the crystalline grain bigger and more even. The crystallization result is better.

Significantly, after the step 5 is accomplished, as shown in FIG. 12, the metal mesh film 3 having metal silicide is moved up on the polysilicon layer 5. Now, the metal mesh film 3 having metal silicide, the polysilicon layer 5, the buffer layer 2 stack up from top to bottom in orders.

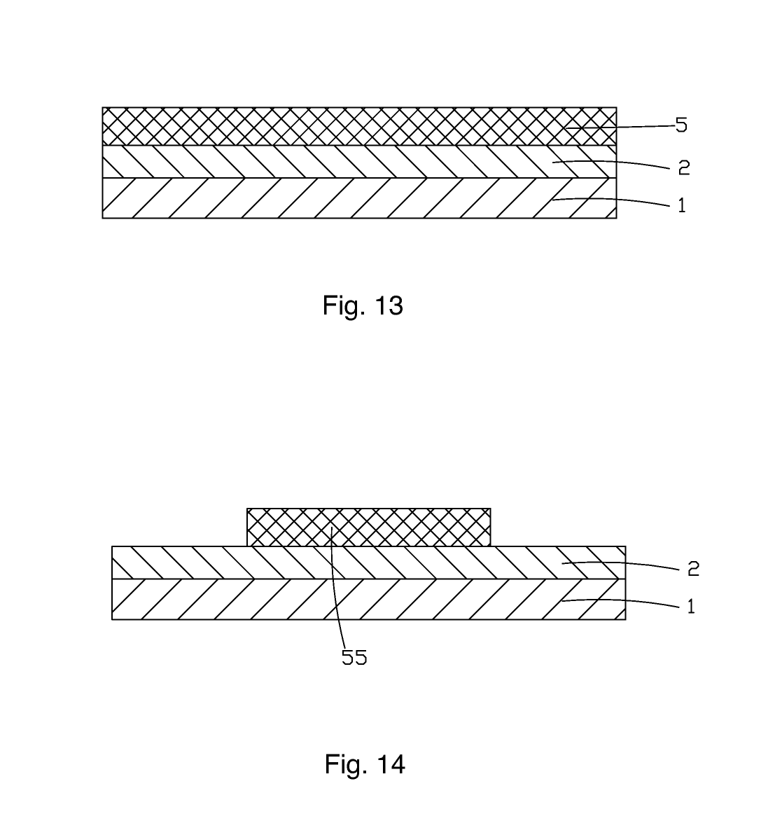

step 6, as shown in FIG. 13, removing the metal mesh film 3 having metal silicide.

Because the metal mesh film 3 having metal silicide, the polysilicon layer 5, the buffer layer 2 stack up from top to bottom in orders after the step 5, the metal mesh film 3 having metal silicide is at the most top position which is convenient to be removed in the step 6.

Thus, the manufacture of LTPS is accomplished.

The manufacture of LTPS according to the present invention can be applied to manufacture the Top-Gate TFT substrate, the Bottom-Gate TFT substrate and the AMOLED.

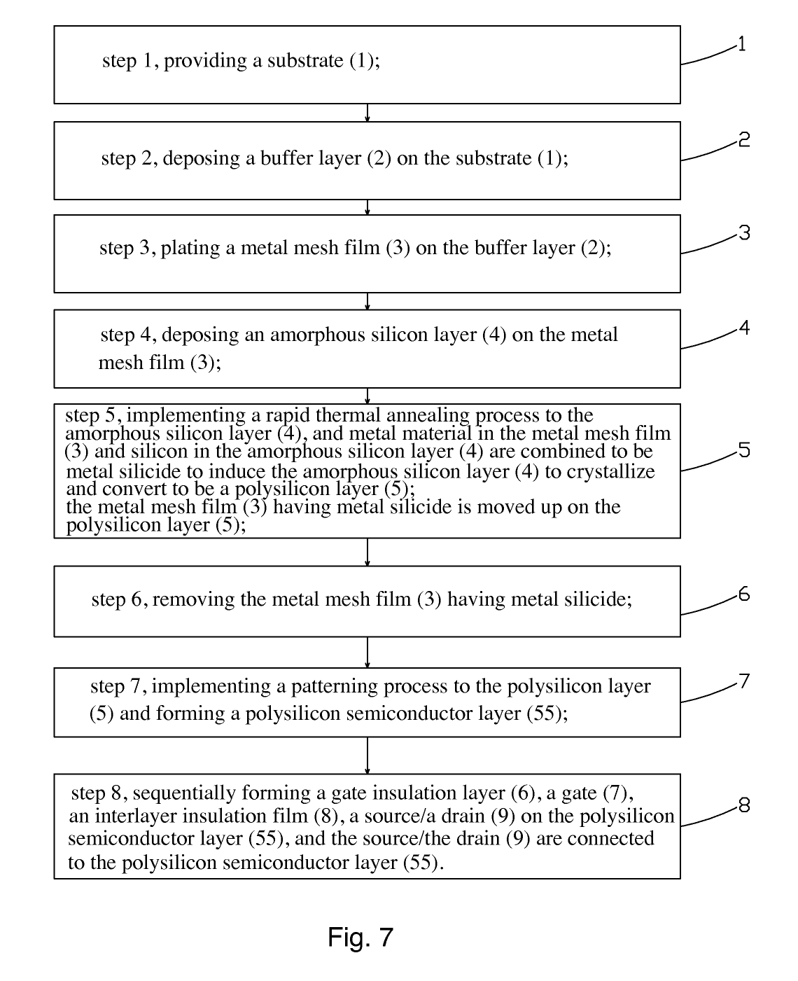

Please refer to FIG. 7 to FIG. 15. On the basis of the aforementioned the manufacture of LTPS, the present invention further provides a manufacture method of a TFT substrate employing the method. The Top-Gate TFT substrate is illustrated. The manufacture method of a TFT substrate comprises steps of:

step 1, providing a substrate 1.

The substrate 1 is a common transparent substrate. Preferably, the substrate 1 is a glass substrate.

step 2, as shown in FIG. 8, deposing a buffer layer 2 on the substrate 1.

Specifically, the buffer layer 2 can be a single SiNx layer, a single SiOx layer, a double SiNx layer, a double SiOx layer or a combination of SiNx layer and SiOx layer.

step 3, as shown in FIG. 9, plating a metal mesh film 3 on the buffer layer 2.

Specifically, the material of the metal mesh film 3 is Aluminum.

step 4, as shown in FIG. 10, deposing an amorphous silicon layer 4 on the metal mesh film 3.

After the step 4 is accomplished, the amorphous silicon layer 4, the metal mesh film 3, the buffer layer 2 stack up from top to bottom in orders.

step 5, as shown in FIG. 11, FIG. 12, implementing a rapid thermal annealing (RTA) process to the amorphous silicon layer 4, and metal material in the metal mesh film 3 and silicon in the amorphous silicon layer 4 are combined to be metal silicide to induce the amorphous silicon layer 4 to crystallize and convert to be a polysilicon layer 5.

Furthermore, the step 5 utilizes the eutectic point characteristic of the metal and silicon interface, and the RTA process under 600° C. with 10 minutes can crystallize amorphous silicon layer 4 to convert to be the polysilicon layer 5. The RTA temperature is effectively reduced. The RTA time is shortened. The amorphous silicon layer 4 rapidly crystallize at lower temperature and no special requirement do for the substrate 1. A common substrate can endure 600° C. The manufacture cost is decreased and application for manufacturing the polysilicon thin film in large scale is possible.

In the RTA process, the metal material in the metal mesh film 3 and silicon in the amorphous silicon layer 4 are combined to be metal silicide to induce the amorphous silicon layer 4 to crystallize. The mesh structure of the metal mesh film 3 is beneficial to induce lateral crystallization with metal which the crystallization is more thoroughly accomplished to make the crystalline grain bigger and more even. The crystallization result is better.

Significantly, after the step 5 is accomplished, as shown in FIG. 12, the metal mesh film 3 having metal silicide is moved up on the polysilicon layer 5. Now, the metal mesh film 3 having metal silicide, the polysilicon layer 5, the buffer layer 2 stack up from top to bottom in orders.

step 6, as shown in FIG. 13, removing the metal mesh film 3 having metal silicide.

Because the metal mesh film 3 having metal silicide, the polysilicon layer 5, the buffer layer 2 stack up from top to bottom in orders after the step 5, the metal mesh film 3 having metal silicide is at the most top position which is convenient to be removed in the step 6.

step 7, as shown in FIG. 14, implementing a patterning process to the polysilicon layer 5 and forming a polysilicon semiconductor layer 55 with photo and etch processes.

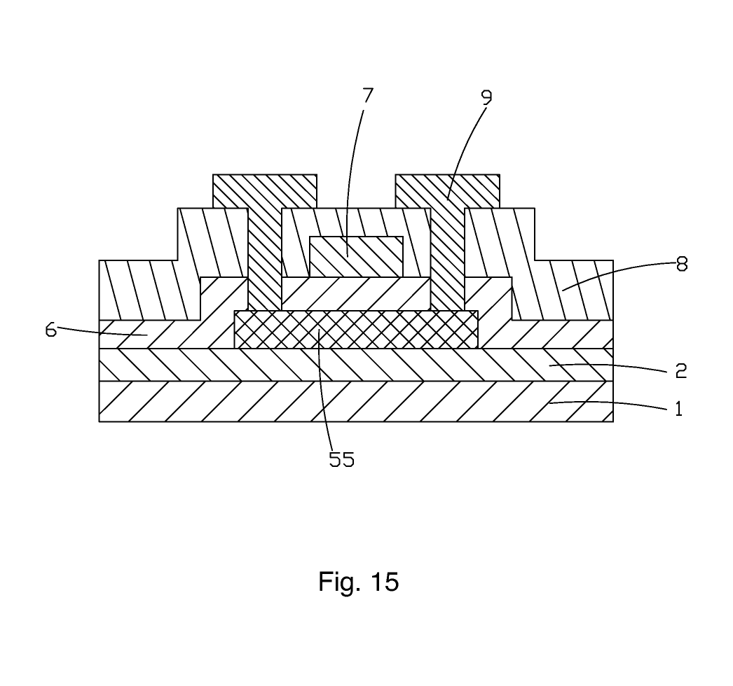

step 8, as shown in FIG. 15, sequentially forming a gate insulation layer 6, a gate 7, an interlayer insulation film 8, a source/a drain 9 on the polysilicon semiconductor layer 55, and the source/the drain 9 are connected to the polysilicon semiconductor layer 55.

Thus, the manufacture of the Top-Gate TFT substrate is accomplished. Because the crystalline grain in the polysilicon layer 5 formed in the step 5 is bigger and more even and the metal mesh film 3 having metal silicide is removed in the step 6, the electric property of the polysilicon semiconductor layer 55 formed in the step 7 can be better and accordingly improve the electric property of the TFT.

In conclusion, according to the manufacture methods of LTPS and the TFT substrate of the present invention, the amorphous silicon layer is deposed on the metal mesh film and the rapid thermal annealing process is implemented to the amorphous silicon layer, and metal material in the metal mesh film and silicon in the amorphous silicon layer are combined to be metal silicide to induce the amorphous silicon layer to crystallize and convert to be a polysilicon layer. Then, the metal mesh film is removed to make the amorphous silicon layer rapidly crystallize at lower temperature, which can effectively reduce the crystallization point, and shorten the crystallization time, and decrease the cost of manufacturing the polysilicon thin film in large scale, and improve the crystallization result to make the crystalline grain bigger and more even for improving the electric property of the TFT.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of LTPS, comprising steps of:
step 1, providing a substrate;
step 2, deposing a buffer layer on the substrate;
step 3, plating a metal mesh film on the buffer layer;
step 4, deposing an amorphous silicon layer on the metal mesh film;
step 5, implementing a rapid thermal annealing process to the amorphous silicon layer, and metal material in the metal mesh film and silicon in the amorphous silicon layer are combined to be metal silicide to induce the amorphous silicon layer to crystallize and convert to be a polysilicon layer;
the metal mesh film having metal silicide is moved up on the polysilicon layer;
step 6, removing the metal mesh film having metal silicide.

2. The manufacture method of LTPS according to claim 1, wherein material of the metal mesh film is Aluminum.

3. The manufacture method of LTPS according to claim 1, wherein in the step 5, the temperature of the rapid thermal annealing process is 600° C. and the time is 10 minutes.

4. The manufacture method of LTPS according to claim 1, wherein the buffer layer is a single SiNx layer, a single SiOx layer, a double SiNx layer, a double SiOx layer or a combination of SiNx layer and SiOx layer.

5. A manufacture method of a TFT substrate, comprising steps of:
step 1, providing a substrate;
step 2, deposing a buffer layer on the substrate;
step 3, plating a metal mesh film on the buffer layer;
step 4, deposing an amorphous silicon layer on the metal mesh film;
step 5, implementing a rapid thermal annealing process to the amorphous silicon layer, and metal material in the metal mesh film and silicon in the amorphous silicon layer are combined to be metal silicide to induce the amorphous silicon layer to crystallize and convert to be a polysilicon layer;
the metal mesh film having metal silicide is moved up on the polysilicon layer;
step 6, removing the metal mesh film having metal silicide;
step 7, implementing a patterning process to the polysilicon layer and forming a polysilicon semiconductor layer;
step 8, sequentially forming a gate insulation layer, a gate, an interlayer insulation film, a source/a drain on the polysilicon semiconductor layer, and the source/the drain are connected to the polysilicon semiconductor layer.

6. The manufacture method of the TFT substrate according to claim 5, wherein material of the metal mesh film is Aluminum.

7. The manufacture method of the TFT substrate according to claim 5, wherein in the step 5, the temperature of the rapid thermal annealing process is 600° C. and the time is 10 minutes.

8. The manufacture method of the TFT substrate according to claim 5, wherein the buffer layer is a single SiNx layer, a single SiOx layer, a double SiNx layer, a double SiOx layer or a combination of SiNx layer and SiOx layer.

9. The manufacture method of the TFT substrate according to claim 5, wherein the step 7 employs photo and etch processes to implement the patterning process to the polysilicon layer.

10. A manufacture method of LTPS, comprising steps of:
step 1, providing a substrate;
step 2, deposing a buffer layer on the substrate;
step 3, plating a metal mesh film on the buffer layer;
step 4, deposing an amorphous silicon layer on the metal mesh film;
step 5, implementing a rapid thermal annealing process to the amorphous silicon layer, and metal material in the metal mesh film and silicon in the amorphous silicon layer are combined to be metal silicide to induce the amorphous silicon layer to crystallize and convert to be a polysilicon layer;
the metal mesh film having metal silicide is moved up on the polysilicon layer;
step 6, removing the metal mesh film having metal silicide;
wherein material of the metal mesh film is Aluminum;
wherein in the step 5, the temperature of the rapid thermal annealing process is 600° C. and the time is 10 minutes;
wherein the buffer layer is a single SiNx layer, a single SiOx layer, a double SiNx layer, a double SiOx layer or a combination of SiNx layer and SiOx layer.
